(19) United States
(12) Patent Application Publication
(10) Pub. No.: US 2025/0099867 A1
(43) Pub. Date: Mar. 27, 2025

(54) VAPORIZER AND LIQUID MATERIAL VAPORIZING DEVICE

(71) Applicant: HORIBA STEC, Co., Ltd., Kyoto-shi (JP)

(72) Inventor: Keisuke NISHIWAKI, Kyoto-shi (JP)

(21) Appl. No.: 18/892,220

(22) Filed: Sep. 20, 2024

(30) Foreign Application Priority Data
Sep. 22, 2023 (JP) 2023-158924

(51) Int. Cl. B01B 1/00; H01L 21/67

(52) U.S. Cl. CPC B01B 1/005; H01L 21/67017

(57) ABSTRACT

A vaporizer that heats and vaporizes liquid material includes a spray chamber, a plurality of heating channels, and a tapered portion. The liquid material is sprayed into the spray chamber. The plurality of heating channels extends from the spray chamber to at least an axial direction one side. The tapered portion is tapered off toward the axial direction in a communication portion between the spray chamber and the heating channel.

### CROSS-REFERENCE TO RELATED APPLICATIONS

This application is based upon and claims the benefit of priority from the corresponding Japanese Patent Application No. 2023-158924 filed Sep. 22, 2023, the entire contents of which are hereby incorporated by reference.

### BACKGROUND OF THE INVENTION

### Field of the Invention

The present invention relates to a vaporizer and a liquid material vaporizing device.

### Description of Related Art

In a vaporizer of a direct liquid injection (DLI) method, a gas-liquid mixture in which liquid material and carrier gas are mixed is sprayed through a nozzle into a vaporizing chamber, so as to vaporize the liquid material. Further, in recent years, along with increasing film forming area in semiconductor manufacturing process, it is required to vaporize liquid material at large flow rate and supply the same to a semiconductor manufacturing apparatus.

For instance, as described in JP-A-2010-67906, droplet-like liquid raw material and carrier gas are introduced into a diameter expanded space of the vaporizing chamber. The vaporizing chamber includes the diameter expanded space, a guidance space, and a lead-out space. The guidance space is constituted of a plurality of guide holes (hereinafter referred to as heating channels) formed vertically from up to down, so as to lead droplets of the liquid raw material introduced into the diameter expanded space to the lead-out space. The droplets of the liquid raw material are vaporized while passing through the diameter expanded space, the guidance space, and the lead-out space.

However, when the liquid material is vaporized at large flow rate through a plurality of heating channels as described in JP-A-2010-67906, residue of the liquid material may adhere to a communication portion to the heating channel. If amount of the adhered residue increases, the heating channel may be closed by the residue, or flow rate of the liquid raw material in the heating channel may be decreased. In the latter case, poor vaporization may occur as the flow rate increases in other heating channel.

### SUMMARY OF THE INVENTION

The present invention is made to solve the above problem, and its object is to ensure that the liquid material flows in each of the heating channels of the vaporizer, and that the liquid material is sufficiently vaporized even at large flow rate.

A vaporizer according to an aspect of the present invention heats and vaporizes liquid material. The vaporizer includes a spray chamber, a plurality of heating channels, and a tapered portion. The liquid material is sprayed into the spray chamber. The plurality of heating channels extend from the spray chamber to at least axial direction one side. The tapered portion is tapered off toward the axial direction in a communication portion between the spray chamber and the heating channel.

A liquid material vaporizing device according to another aspect of the present invention includes the vaporizer described above and a liquid material supply portion that supplies the liquid material to the vaporizer.

Other features and advantages of the present invention will become more apparent from the description of the embodiment given below.

According to the present invention, it is possible to ensure that the liquid material flows in each of the heating channels of the vaporizer, and that the liquid material is sufficiently vaporized even at large flow rate.

### BRIEF DESCRIPTION OF THE DRAWINGS

FIG. 1 is a cross-sectional view schematically illustrating a general structure example of a liquid material vaporizing device according to an embodiment of the present invention.

FIG. 2 is a perspective cross-sectional view illustrating a structure example of a vaporizer provided to the liquid material vaporizing device.

FIG. 3A is an enlarged cross-sectional view of a first structure example of a communication portion between a spray chamber and each of heating channels in the vaporizer.

FIG. 3B is a cross-sectional view of the communication portion of the first structure example, viewed diagonally from the other side in an axial direction.

FIG. 4A is a cross-sectional view illustrating a first modified example of a cylinder portion.

FIG. 4B is a cross-sectional view illustrating a second modified example of the cylinder portion.

FIG. 5A is an enlarged cross-sectional view of a second structure example of the communication portion.

FIG. 5B is a cross-sectional view of the communication portion of the second structure example, viewed diagonally from the other side in the axial direction.

FIG. 6A is an enlarged cross-sectional view of a third structure example of the communication portion.

FIG. 6B is a cross-sectional view of the communication portion of the third structure example, viewed diagonally from the other side in the axial direction.

FIG. 7A is an enlarged cross-sectional view of fourth and fifth structure examples of the communication portion.

FIG. 7B is a cross-sectional view of the communication portion of the fourth structure example, viewed diagonally from the other side in the axial direction.

FIG. 7C is a cross-sectional view of the communication portion of the fifth structure example, viewed diagonally from the other side in the axial direction.

FIG. 8A is an enlarged cross-sectional view of a sixth structure example of the communication portion.

FIG. 8B is a cross-sectional view of the communication portion of the sixth structure example, viewed diagonally from the other side in the axial direction.

FIG. 9 is a perspective view of a part of a static mixer as a heat exchange element provided to the vaporizer.

### LIST OF REFERENCE CHARACTERS

1: liquid material vaporizing device, 2: liquid material supply portion, 21: gas-liquid mixing portion, 22: actuator, 3: vaporizer, 31: heater, 32: cylinder portion, 321: frustum portion, 322: tube portion, 323: frustum portion, 4: connection portion, 11: nozzle, 111: spray hole, 12: vaporizing portion, 121: spray chamber, 122, 122a: heating channel, 123, 123a: communication portion, 124: protruding portion, 13: tapered portion, 131: first tapered portion, 132: second tapered portion, 133: pointed portion, 14: residue preventing layer, 15: heat exchange element, 150: fin, 151: first fin, 152: second fin, CG: carrier gas, LQ: liquid material, MG: gas-liquid mixture, MGa: mixed gas, CA: center axis, JF, JFa: first axis, JT: second axis, Da: axial direction one side, Db: axial direction other side

### DETAILED DESCRIPTION OF THE PREFERRED EMBODIMENTS

Hereinafter, an exemplary embodiment of the present invention is described with reference to the drawings.

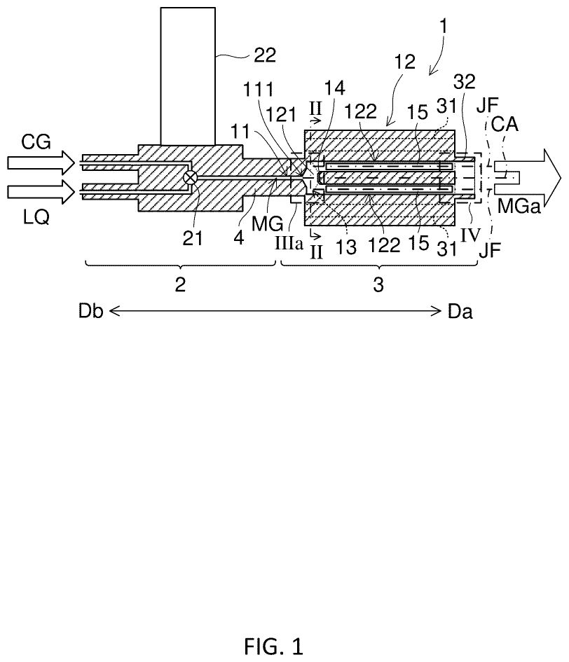

FIG. 1 is a cross-sectional view schematically illustrating a general structure example of a liquid material vaporizing device 1 according to an embodiment of the present invention. The liquid material vaporizing device 1 is disposed in a semiconductor manufacturing apparatus (not shown), for example. The liquid material vaporizing device 1 includes a liquid material supply portion 2 and a vaporizer 3. The liquid material supply portion 2 and the vaporizer 3 are connected to each other via a connection portion 4, but they may be connected directly without the connection portion 4.

The liquid material supply portion 2 supplies liquid material LQ to the vaporizer 3. This liquid material supply portion 2 is constituted of a flow rate control valve (flow rate adjust valve), for example. In particular, in this embodiment, the liquid material supply portion 2 supplies a gas-liquid mixture MG, in which the liquid material LQ and carrier gas CG are mixed, to the vaporizer 3. The liquid material LQ described above is liquid material of a desired gas that is used in semiconductor manufacturing process. As the carrier gas CG described above, an inert gas such as nitrogen or argon can be used, for example.

Mixing of the liquid material LQ and the carrier gas CG is performed in a gas-liquid mixing portion 21. The gas-liquid mixing portion 21 is constituted of a valve seat member and a valve body member, for example. The valve body member described above is driven by an actuator 22, so as to contact or separate from the valve seat member. When the valve body member contacts or separates from the valve seat member, supply of the liquid material LQ, which flows in a gap between the valve seat member and the valve body member, is turned off or on. In this way, on and off of mixing the liquid material LQ with the carrier gas CG can be switched. The actuator 22 is constituted of a piezo stack in which a plurality of piezo elements are stacked, for example, but it may be constituted of a solenoid or the like.

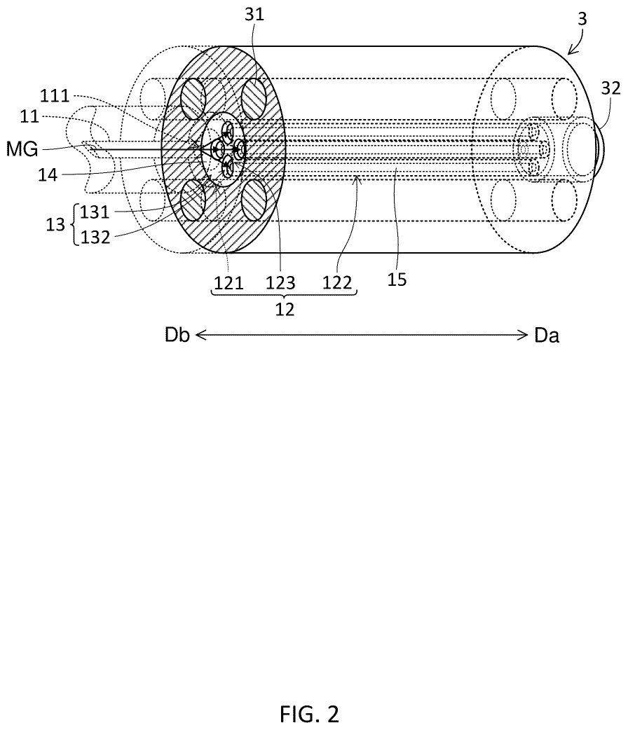

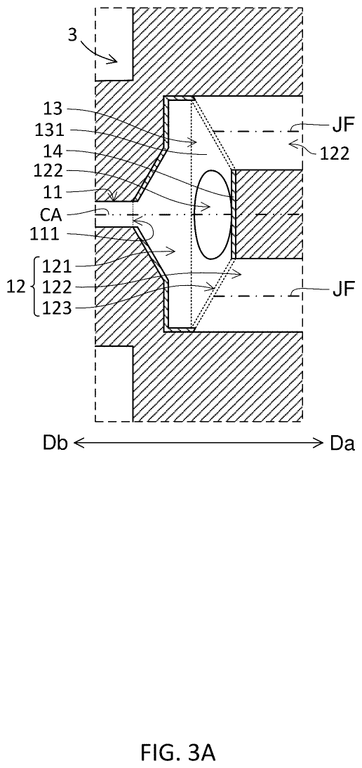

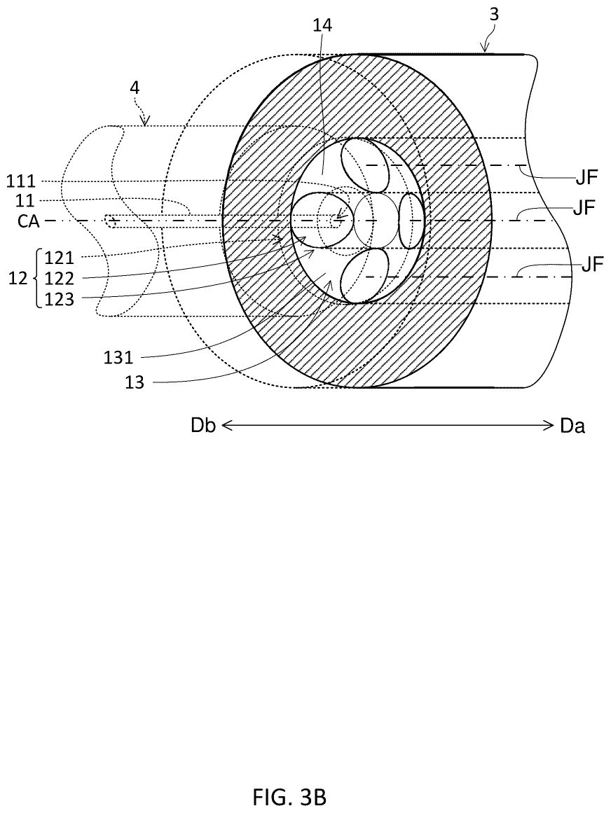

The vaporizer 3 heats the gas-liquid mixture MG and vaporizes the liquid material LQ. FIG. 2 is a perspective cross-sectional view illustrating a structure example of the vaporizer 3 provided to the liquid material vaporizing device 1 described above. FIG. 3A is an enlarged cross-sectional view of a first structure example of a communication portion 123 between a spray chamber 121 described later and each of heating channels 122 described later, in the vaporizer 3 described above. FIG. 3B is a cross-sectional view of the communication portion 123 described above of the first structure example, viewed diagonally from an axial direction other side Db. Note that the communication portion 123 includes an axial direction one end (in particular, an axial direction one end surface) of the spray chamber 121, and an axial direction other end (in particular, an inner peripheral surface at the axial direction other end) of each of the heating channels 122. Note that the communication portion 123 may further include an inner peripheral surface of the axial direction one end of the spray chamber 121. FIGS. 2 and 3B illustrate cross-section structures of the vaporizer 3 imaginarily cut along a plane including a two-dot dashed line II-II in FIG. 1, the plane being perpendicular to the axial direction. FIG. 3 A corresponds to a cross-section structure of a part IIIa enclosed by a broken line in FIG. 1. In addition, for easy understanding of the structure, a heater 31 is not illustrated in FIG. 3B.

The vaporizer 3 includes a nozzle 11 and a vaporizing portion 12.

The vaporizing portion 12 of the vaporizer 3 has a structure of a cylindrical shape extending along a center axis CA in the axial direction, and includes the spray chamber 121 and the plurality of heating channels 122 inside. Each of the heating channels 122 extends from the spray chamber 121 toward the axial direction one end of the vaporizing portion 12, to at least an axial direction one side Da. The axial direction other end of each of the heating channels 122 is an opening through which the sprayed body of the gas-liquid mixture MG flows in, and is disposed at the axial direction one end of the spray chamber 121 (in particular, at the communication portion 123). The axial direction one end of each of the heating channels 122 is an opening through which the mixed gas MGa flows out, and is disposed in the axial direction one end surface of the vaporizing portion 12.

Note that in this embodiment, all the heating channels 122 extend linearly to the axial direction one side Da. However, this example does not exclude a structure in which all the heating channels 122 do not extend similarly. For instance, viewed from the axial direction, the heating channels 122 may be disposed radially from the center near the center axis CA. In addition, extending shapes of some heating channels 122 may be different from those of other part of heating channels 122. In addition, at least one of the heating channels 122 may not extend linearly but may extend in a curved manner, or may extend in a direction crossing the axial direction one side Da, as long as the axial direction one end thereof is disposed on the axial direction one end surface of the vaporizing portion 12. Here, the direction crossing the axial direction one side Da is a direction that includes not only a component of the axial direction one side Da but also at least one of an axial direction component and a circumferential direction component.

A spray hole 111 of the nozzle 11 is disposed in the axial direction other end surface of the spray chamber 121. The nozzle 11 sprays the gas-liquid mixture MG supplied from the liquid material supply portion 2 into the spray chamber 121 through the spray hole 111. The sprayed body of the gas-liquid mixture MG flows from the spray chamber 121 to each of the heating channels 122.

In addition, a plurality of the heaters 31, which heat the vaporizing portion 12 (in particular, the heating channels 122), are embedded in the vaporizer 3. The heater 31 has a column shape extending in the axial direction, and a plurality of them are arranged outside the spray chamber 121 and the plurality of heating channels 122, in a circumferential direction around the center axis CA. In other words, the plurality of heaters 31 are arranged outside the spray chamber 121 and the plurality of heating channels 122 in the radial direction, so as to surround them.

In addition, the vaporizer 3 further includes a cylinder portion 32. The cylinder portion 32 has a cylindrical shape enclosing the center axis CA, and extends to the axial direction one side Da at the axial direction one end of the vaporizer 3. Specifically, the cylinder portion 32 extends from the axial direction one end surface of the vaporizing portion 12 to the axial direction one side Da. The axial direction one end of the cylinder portion 32 is connected to a not shown semiconductor manufacturing apparatus. The axial direction other end of the cylinder portion 32 is disposed outside in the radial direction of the axial direction one end of the plurality of heating channels 122, on the axial direction one end surface of the vaporizing portion 12, so as to surround them. In this embodiment, the axial direction the other end of the cylinder portion 32 surround the axial direction one end of all the heating channels 122. Note that in this embodiment, the axial direction one end of each of the heating channels 122 contacts an inner circumferential edge of the axial direction the other end of the cylinder portion 32 (see FIGS. 1 and 2). However, without limiting to this example, the axial direction one end of at least one of the heating channels 122 may be apart from the axial direction the other end of the cylinder portion 32 inward in the radial direction.

The mixed gas MGa flowing out from the axial direction one end of each of the heating channels 122 confluents inside the cylinder portion 32 and is supplied to a not-shown semiconductor manufacturing apparatus. Note that the cylinder portion 32 may have a cylindrical shape or a square tube shape.

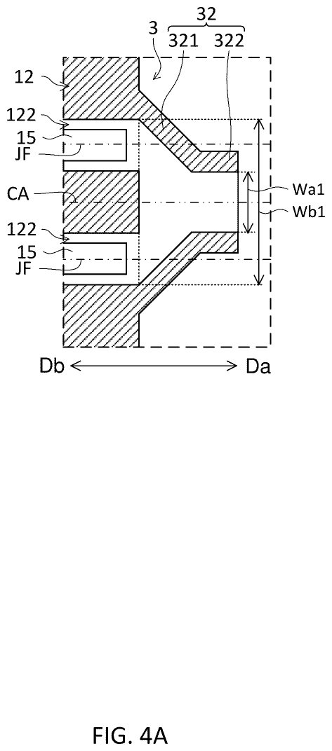

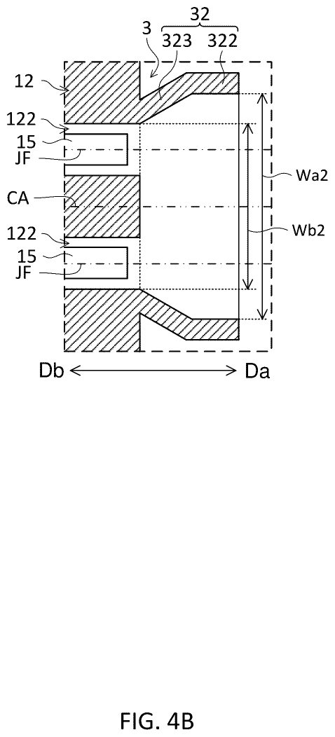

In this embodiment, as illustrated in FIGS. 1 and 2, inner diameter of the cylinder portion 32 is constant along the axial direction. However, without limiting to the example of FIGS. 1 and 2, the inner diameter of the cylinder portion 32 at the axial direction one end may be different from that at the axial direction other end. FIG. 4A is a cross-sectional view illustrating a first modified example of the cylinder portion 32. FIG. 4B is a cross-sectional view illustrating a second modified example of the cylinder portion 32. Note that FIGS. 4A and 4B correspond to a cross-section structure of a part IV enclosed by the broken line in FIG. 1.

For instance, as illustrated in FIG. 4A, inner diameter Wa1 of the cylinder portion 32 at the axial direction one end may be smaller than inner diameter Wb1 of the same at the axial direction other end. Specifically, in FIG. 4A, the cylinder portion 32 includes a frustum portion 321 and a tube portion 322. The frustum portion 321 is a cylinder having a frustum shape, and extends from the axial direction one end surface of the vaporizing portion 12 to the axial direction one side Da. The inner diameter of the frustum portion 321 is tapered off to decrease toward the axial direction one side Da. The tube portion 322 extends from the axial direction one end of the frustum portion 321 to the axial direction one side Da. The inner diameter of the tube portion 322 is constant along the axial direction. In FIG. 4A, the axial direction one end of the tube portion 322 is the axial direction one end of the cylinder portion 32. The axial direction other end of the cylinder portion 32 is the axial direction other end of the frustum portion 321. Note that the example of FIG. 4A does not exclude a structure in which the tube portion 322 is eliminated. In other words, the axial direction one end of the cylinder portion 32 may be the axial direction one end of the frustum portion 321.

Alternatively, as illustrated in FIG. 4B, inner diameter Wa2 of the cylinder portion 32 at the axial direction one end may be larger than inner diameter Wb2 of the same at the axial direction other end. Specifically, in FIG. 4B, the cylinder portion 32 has the tube portion 322 and a frustum portion 323. The frustum portion 323 is a cylinder having a frustum shape, and extends from the axial direction one end surface of the vaporizing portion 12 to the axial direction one side Da. The inner diameter of the frustum portion 323 is inverse tapered to increase toward the axial direction one side Da. In FIG. 4B, the axial direction other end of the frustum portion 323 is the axial direction other end of the cylinder portion 32. The tube portion 322 extends from the axial direction one end of the frustum portion 323 to the axial direction one side Da. The tube portion 322 of FIG. 4B has the same structure as the tube portion 322 of FIG. 4A. Note that the example of FIG. 4B does not exclude a structure in which the tube portion 322 is eliminated. In other words, the axial direction one end of the cylinder portion 32 may be the axial direction one end of the frustum portion 323.

As the inner diameter Wa1 (or Wa2) at the axial direction one end of the cylinder portion 32 is different from the inner diameter Wb1 (or Wb2) at the axial direction other end, the inner diameter Wa1 (or Wa2) of a connection port with a not shown semiconductor manufacturing apparatus (i.e., the axial direction one end of the cylinder portion 32) can be any size. In other words, the inner diameter Wa1 (or Wa2) is not affected by the inner diameter Wb1 (or Wb2) of the cylinder portion 32 at the axial direction other end, or by arrangement of the heating channels 122 at the axial direction one end in the axial direction one end surface of the vaporizing portion 12. Therefore, the inner diameter Wa1 (or Wa2) can be an appropriate size for connection with a not shown semiconductor manufacturing apparatus.

In addition, in the cylinder portion 32, if a tube-like member having a constant inner diameter different from the inner diameter Wa1, Wa2 of the tube portion 322 is disposed instead of the frustum portion 321, 323, a step having a surface perpendicular to the axial direction is formed, for example, at inner side of the connection part between the tube-like member and the tube portion 322. In this case, a flow channel cross-section area of the mixed gas MGa in the cylinder portion 32 rapidly changes at the step described above. For this reason, the mixed gas MGa tends to reside at the step, and residue thereof tends to adhere thereto. In particular, if the inner diameter Wb1 of the cylinder portion 32 at the axial direction other end is larger than the inner diameter Wa1 of the tube portion 322, the step described above is formed on the axial direction other side Db of the tube portion 322 (i.e., an upstream side of the mixed gas MGa). Therefore, tendency of residence of the mixed gas MGa and adhesion of residue thereof is conspicuous particularly when Wa1<Wb1 is satisfied.

In contrast, in FIGS. 4A and 4B, the step described above is not formed at a connection part between the tube portion 322 and the frustum portion 321, 323, and hence the mixed gas MGa flowing near the inner peripheral surface of the cylinder portion 32 smoothly flows to the tube portion 322 along the inner peripheral surface of the frustum portion 321, 323 having a taper shape. Thus, the mixed gas MGa does not reside at the connection part between the tube portion 322 and the frustum portion 321, 323, and hence adhesion of residue thereof can be effectively suppressed or prevented.

In particular, in FIG. 4A, the step described above is not formed on the axial direction other side Db of the connection part between the frustum portion 321 and the tube portion 322, and hence the flow channel cross-section area of the mixed gas MGa in the cylinder portion 32 does not rapidly decrease. In addition, the inner diameter of the axial direction one end of the frustum portion 321 is the same as the inner diameter of the axial direction other end of the tube portion 322. Therefore, residence of the mixed gas MGa and adhesion of residue thereof at the inner peripheral surface of the cylinder portion 32 (in particular, near the connection part between the frustum portion 321 and the tube portion 322) can be securely suppressed or prevented.

In addition, in FIG. 4B, as the frustum portion 323 is disposed, the flow channel cross-section area of the mixed gas MGa in the cylinder portion 32 increases toward the axial direction one side Da. For this reason, the mixed gas MGa does not reside on the axial direction other side Db of the cylinder portion 32, and smoothly flows to a not shown semiconductor manufacturing apparatus. Thus, it is possible to prevent residue of the mixed gas MGa from adhering to the axial direction other side Db of the cylinder portion 32. Therefore, the mixed gas MGa can be securely allowed to flow to the semiconductor manufacturing apparatus, and a large amount of the mixed gas MGa can be sufficiently supplied to the semiconductor manufacturing apparatus.

Note that in this embodiment, as illustrated in FIGS. 4A and 4B, the axial direction one end of each of the heating channels 122 contacts the axial direction the other end of the cylinder portion 32 (the inner peripheral surface thereof). In this way, it is possible to more effectively prevent residence of the mixed gas MGa on the axial direction other side Db of the cylinder portion 32. Therefore, the mixed gas MGa can be allowed to flow more smoothly to the semiconductor manufacturing apparatus. However, this example does not exclude a structure in which the axial direction one end of at least one of the heating channels 122 is apart from the axial direction the other end of the cylinder portion 32 (the inner peripheral surface thereof) inward in the radial direction.

The liquid material LQ contained in the sprayed gas-liquid mixture MG is heated and vaporized in the vaporizing portion 12 (in particular, in the heating channel 122). The mixed gas MGa of the vaporized liquid material LQ and the carrier gas CG is discharged from the axial direction one end of each of the heating channels 122 to a not shown semiconductor manufacturing apparatus.

In addition, at least some of the heating channels 122 are arranged in the circumferential direction around the center axis CA. The center axis CA passes through the spray hole 111 disposed in the axial direction other end surface of the spray chamber 121, and extends in the axial direction. For instance, in this embodiment, all the heating channels 122 are arranged in the circumferential direction around the center axis CA (see, for example, FIG. 2).

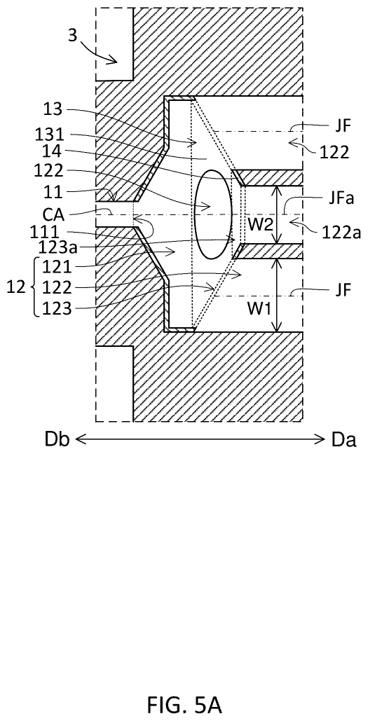

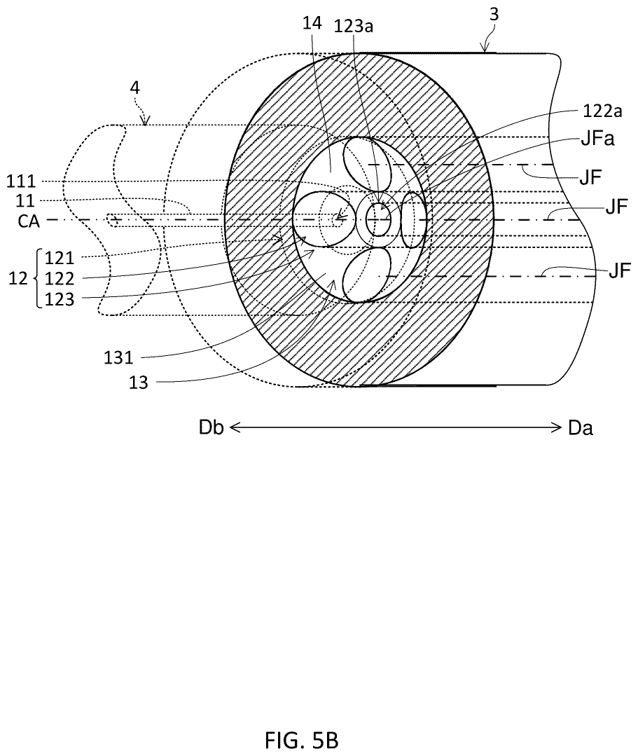

Here, as illustrated in FIGS. 5A, 5B, and the like, it may be possible that some of the heating channels 122a are arranged in the circumferential direction around the center axis CA, and that other part of heating channels 122 are arranged inward in the radial direction of the heating channels 122 arranged in the circumferential direction. FIG. 5A is an enlarged cross-sectional view of a second structure example of the communication portion 123 described above. FIG. 5B is a cross-sectional view of the communication portion 123 described above of the second structure example, viewed diagonally from the axial direction other side Db. Note that FIG. 5A corresponds to the cross-section structure of the part IIIa enclosed by the broken line in FIG. 1. FIG. 5B corresponds to the cross-section structure of the vaporizer 3 imaginarily cut along the plane including the two-dot dashed line II-II in FIG. 1, the plane being perpendicular to the axial direction. In addition, for easy understanding of the structure, the heater 31 is not illustrated in FIG. 5B.

In FIGS. 5A and 5B, the axial direction other end of the other part of heating channels 122a faces the spray hole 111 in the axial direction. In addition, a first axis JFa, which passes through the center of the other part of heating channels 122a and extends in the axial direction, preferably passes through the spray hole 111, and more preferably coincides with the center axis CA of the vaporizing portion 12.

In this way, the sprayed body of the liquid material LQ can flow more uniformly in the some heating channels 122 arranged in the circumferential direction. Further, a part of the sprayed body of the gas-liquid mixture MG sprayed through the spray hole 111 can be allowed to directly flow into the other part of heating channels 122a. Thus, residue of the liquid material LQ hardly adhere to the communication portion 123a between the spray chamber 121 and the other part of heating channels 122a, and its vicinity.

In this case, it is more preferred that inner diameter W2 of the other part of heating channels 122a is smaller than inner diameter W1 of the some heating channels 122 arranged in the circumferential direction (see FIG. 5A). In this way, the flow rate of the sprayed body in the other part of heating channels 122a can be decreased to be close to the flow rate of the sprayed body in each of the some heating channels 122 arranged in the circumferential direction. In other words, a flow rate difference between them can be reduced or eliminated. This is because the sprayed body tends to flow more in the other part of heating channels 122a than each of the some heating channels 122. Thus, even in the arrangement as illustrated in FIG. 5A, the flow rate of the sprayed body flowing in each of the heating channels 122 and 122a can be more equalized. Therefore, poor vaporization of the liquid material LQ due to excessive flow rate (particularly in the other part of heating channels 122a) can be suppressed or prevented. However, this example does not exclude a structure in which W2>W1 is satisfied.

In addition, the example describe above does not exclude a structure in which at least some of the heating channels 122 are not arranged in the circumferential direction around the center axis CA, and does not exclude a structure in which the axial direction other end of other some heating channels 122a does not face the spray hole 111 in the axial direction. For instance, when viewing from the axial direction other side Db, the plurality of heating channels 122 may be arranged at random in a two-dimensional manner.

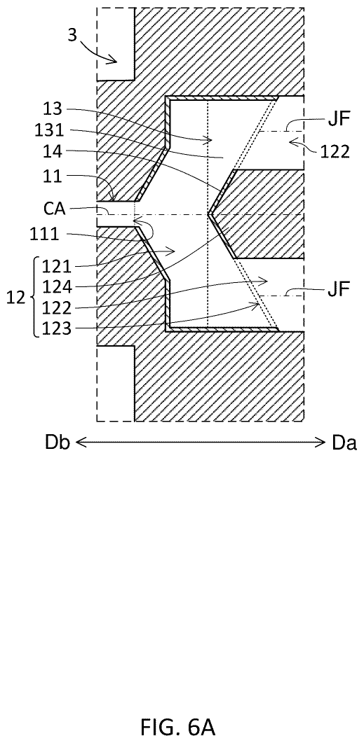

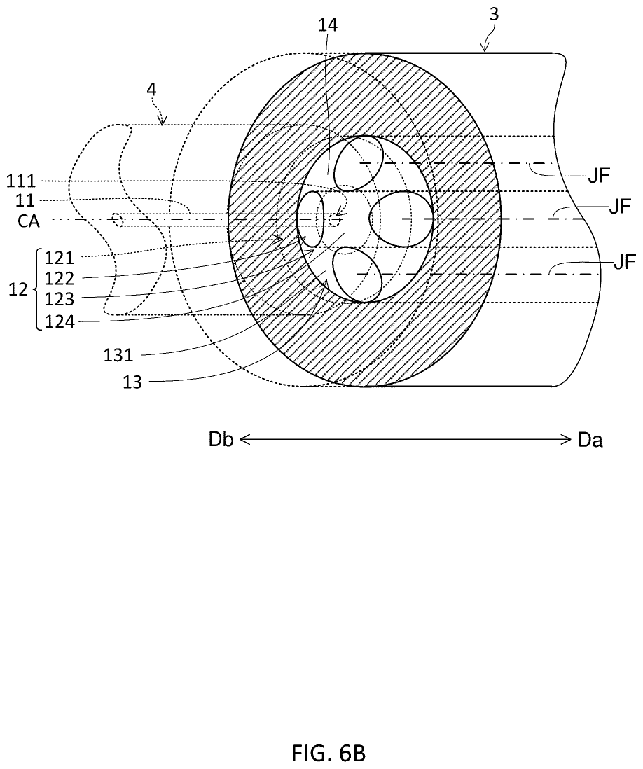

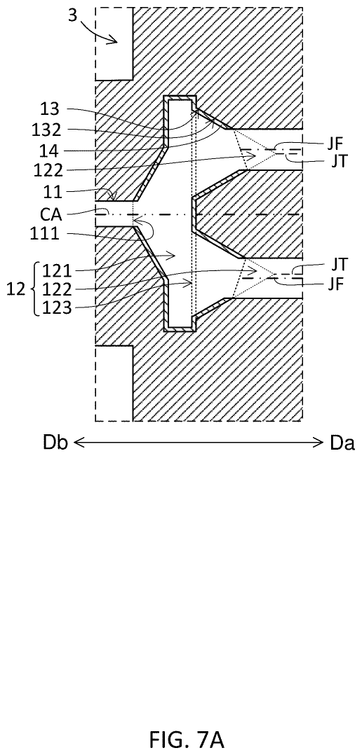

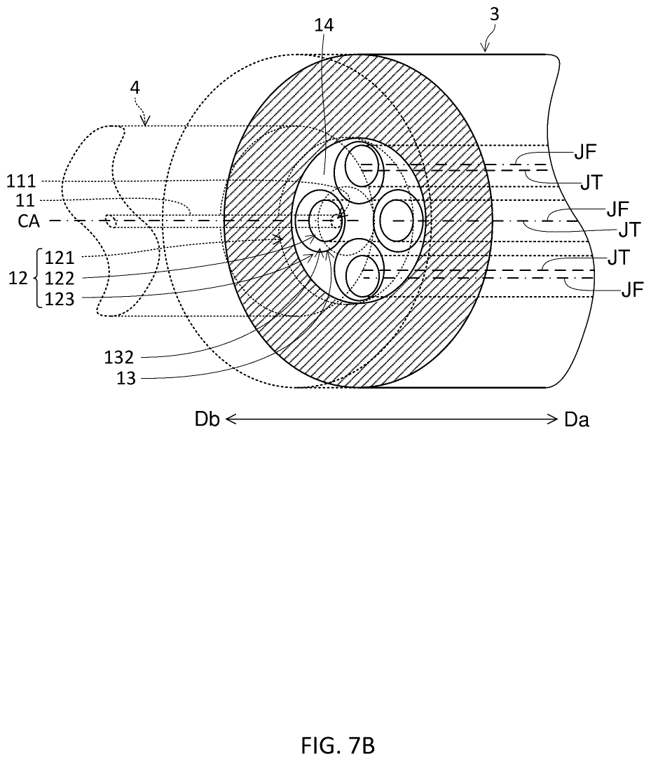

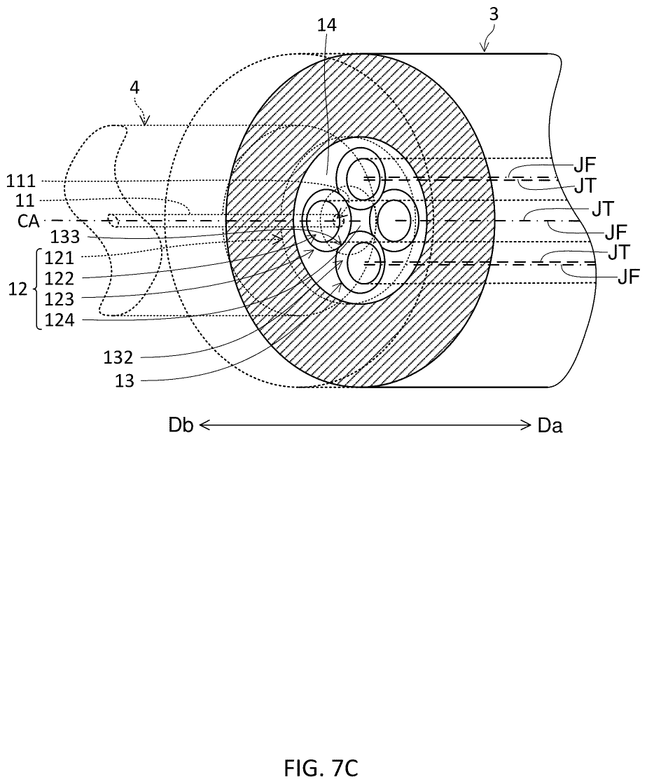

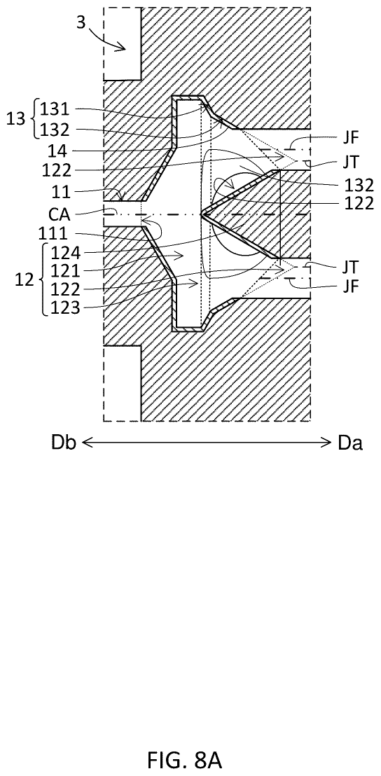

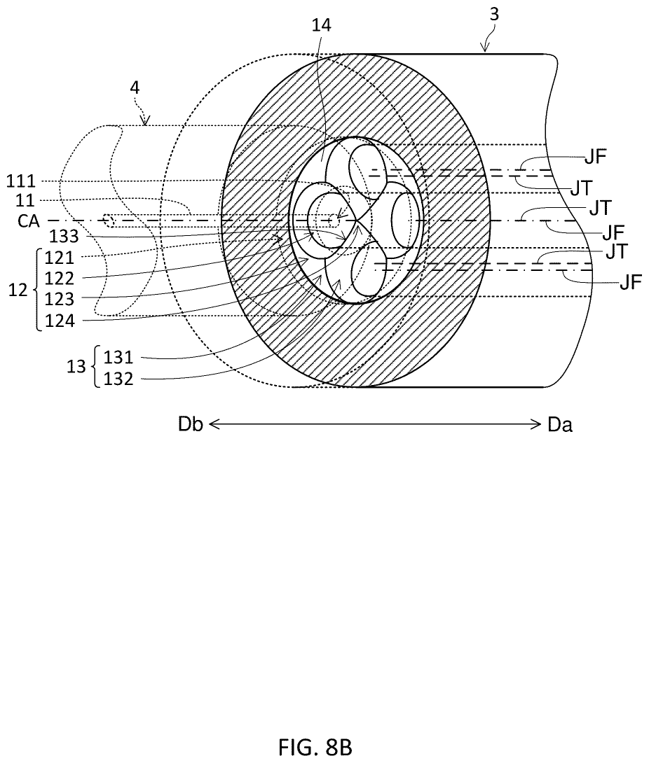

In addition, as illustrated in FIGS. 3A, 3B, and 5A to 8B, the spray chamber 121 of the vaporizing portion 12 of the vaporizer 3 further includes a tapered portion 13. The tapered portion 13 is disposed at the communication portion 123 between the spray chamber 121 and each of the heating channels 122. For instance, as described later, the tapered portion 13 is disposed at least at one of the axial direction one end of the spray chamber 121 (in particular, the axial direction one end surface of the spray chamber 121 facing the axial direction other side Db), and the axial direction other end of each of the heating channels 122 (in particular, the inner peripheral surface at the axial direction other end). In addition, the tapered portion 13 may be disposed on the inner peripheral surface of the spray chamber 121 at the axial direction one end. The tapered portion 13 is tapered off in the axial direction in the communication portion 123 between the spray chamber 121 and the heating channel 122. FIG. 6A is an enlarged cross-sectional view of a third structure example of the communication portion 123 described above. FIG. 6B is a cross-sectional view of the communication portion 123 described above of the third structure example, viewed diagonally from the axial direction other side Db. FIG. 7A is an enlarged cross-sectional view of fourth and fifth structure examples of the communication portion 123 described above. FIG. 7B is a cross-sectional view of the communication portion 123 described above of the fourth structure example, viewed diagonally from the axial direction other side Db. FIG. 7C is a cross-sectional view of the communication portion 123 described above of the fifth structure example, viewed diagonally from the axial direction other side Db. FIG. 8A is an enlarged cross-sectional view of a sixth structure example of the communication portion 123 described above. FIG. 8B is a cross-sectional view of the communication portion 123 described above of the sixth structure example, viewed diagonally from the axial direction other side Db. Note that FIGS. 6A, 7A, and 8A correspond to the cross-section structure of the part IIIa enclosed by the broken line in FIG. 1. FIGS. 6B, 7B, 7C, and 8B correspond to the cross-section structure of the vaporizer 3 imaginarily cut along the plane including the two-dot dashed line II-II in FIG. 1, the plane being perpendicular to the axial direction. In addition, for easy understanding of the structure, a heater 31 is not illustrated in FIGS. 6B, 7B, 7C, and 8B.

As illustrated in FIGS. 3A, 3B, and 5A to 8A, the tapered portion 13 described above is disposed at the communication portion 123 described above between the spray chamber 121 and each of the heating channels 122, and hence the sprayed body of the gas-liquid mixture MG flows smoothly to each of the heating channels 122, without residing at the communication portion 123 described above. Thus, it is possible to prevent residue of the sprayed liquid material LQ from adhering to the communication portion 123 described above. As a result, it is secured that the liquid material LQ flows in each of the heating channels 122 of the vaporizer 3, and the liquid material LQ can be sufficiently vaporized even in large quantity.

It is preferred that a residue preventing layer 14 that repels the liquid material LQ is disposed on an inner surface of at least one of the spray chamber 121 and the tapered portion 13. In other words, the vaporizer 3 has the residue preventing layer 14. It is more preferred that the residue preventing layer 14 is disposed on the inner surface of the tapered portion 13. For instance, in this embodiment, as illustrated in FIGS. 6A to 8A, the residue preventing layer 14 is disposed on all the inner surfaces of the spray chamber 121 and the tapered portion 13. Note that the residue preventing layer 14 can be disposed by fluororesin coating treatment such as perfluoroalkoxy alkane (PFA) treatment, water repellent treatment using laser irradiation to the inner surface described above, or the like. In this way, the liquid material LQ hardly adhere to the residue preventing layer 14 on the inner surface described above, and hence adhesion of residue of the sprayed body of the liquid material LQ can be effectively suppressed or prevented. However, this example does not exclude a structure in which the residue preventing layer 14 is not disposed on the inner surface of the spray chamber 121 on the axial direction other side Db, and does not exclude a structure in which the residue preventing layer 14 is not disposed on the inner surface of the spray chamber 121 and the tapered portion 13.

In addition, it is preferred that the tapered portion 13 includes a first tapered portion 131, as illustrated in FIGS. 3A to 5B, 8A, and 8B. The first tapered portion 131 is a curved surface that is disposed on the axial direction one end surface of the spray chamber 121, and has a conical shape whose diameter decreases toward the axial direction one side Da or other side Db. In this case, a part of the first tapered portion 131 (e.g. the axial direction other side Db) may be disposed on the inner peripheral surface of the axial direction one end of the spray chamber 121. For instance, in FIGS. 3A to 5B, 8A, and 8B, the first tapered portion 131 corresponds to the axial direction one end to the axial direction other end of the curved surface having the conical shape described above disposed on the axial direction one end surface of the spray chamber 121. Note that the conical shape includes not only a conical shape whose tip is pointed (e.g. a conical shape, a pyramid shape) but also a frustum shape whose tip is flat (e.g. a frustum shape, a prismoid shape). For instance, in FIGS. 3A, 3B, 5A, 5B, 8A, and 8B, the first tapered portion 131 having a conical shape is disposed on the axial direction one end surface of the spray chamber 121, and its outer diameter decreases toward the axial direction one side Da. In addition, in FIGS. 6A and 6B, the first tapered portion 131 having a conical shape is disposed on the axial direction one end surface of the spray chamber 121, and its outer diameter decreases toward the axial direction other side Db. Note that in FIGS. 6A and 6B, the first tapered portion 131 may have a frustum shape.

Thanks to the first tapered portion 131, the surface that is disposed on the axial direction one end surface of the spray chamber 121 and crosses (in particular, is perpendicular to) the axial direction can be reduced or eliminated in the communication portion 123. Thus, in FIGS. 3A, 3B, 5A, 5B, and 8B, the gas-liquid mixture MG can flow smoothly from the spray chamber 121 to each of the heating channels 122 in the communication portion 123. In addition, adhesion of residue of the liquid material LQ to the axial direction one end surface of the spray chamber 121 can be suppressed or prevented. In particular, the adhesion can be suppressed or prevented effectively in FIGS. 3A, 3B, 5A, 5B, 8A, and 8B. For instance, in a vicinity of the first tapered portion 131, the gas flow of the sprayed body flowing from the spray chamber 121 to each of the heating channels 122 flows along the first tapered portion 131 to the axial direction one side Da, and flows into each of the heating channels 122. Thus, residue of the liquid material LQ hardly occurs at the first tapered portion 131. In addition, even if residue occurs, it is swept away by the gas flow to the heating channel 122.

Note that in this embodiment, the center axis (not shown) of the conical shape or the frustum shape of the first tapered portion 131 coincides with the center axis CA of the vaporizing portion 12, and pass through the barycenter of the conical shape or the frustum shape so as to extend in the axial direction. However, this example does not exclude a structure in which the center axis of the first tapered portion 131 does not coincide with the center axis CA. For instance, the center axis of the first tapered portion 131 may extend in a direction diagonally crossing the center axis CA, or may be apart from the center axis CA.

In addition, it is preferred that the tapered portion 13 includes a second tapered portion 132 as illustrated in FIGS. 7A to 8B. Note that in FIGS. 7A to 7C, the tapered portion 13 includes only the second tapered portion 132. In contrast, in FIGS. 8A and 8B, the tapered portion 13 includes both the first tapered portion 131 and the second tapered portion 132.

The second tapered portion 132 is disposed on the inner peripheral surface at the axial direction other end of at least one of the heating channels 122, and is a curved surface having a frustum shape whose outer diameter decreases toward the axial direction one side Da. For instance, in FIGS. 7A to 8B, the second tapered portion 132 of each of the heating channels 122 corresponds to between the axial direction one end and the axial direction other end of the curved surface having the frustum shape described above disposed at the axial direction other end of the heating channel 122. In this way, thanks to the second tapered portion 132, the gas flow of the sprayed body of the liquid material LQ can flow smoothly from the spray chamber 121 to each of the heating channels 122. In addition, as the second tapered portion 132 is disposed, outer diameter of the heating channel 122 at the axial direction other end can be larger than inner diameter of the heating channel 122. Therefore, the area of the surface formed on the axial direction one end surface of the spray chamber 121 can be reduced or eliminated. Thus, occurrence of residue of the liquid material LQ can be suppressed or prevented.

It is more preferred that, in at least two of the heating channels 122 neighboring in the circumferential direction around the center axis CA, the second tapered portions 132 respectively disposed in the heating channels 122 (i.e., the second tapered portions 132 neighboring in the circumferential direction) contact each other in the circumferential direction. It is still more preferred that, in all the heating channels 122 arranged in the circumferential direction, the second tapered portions 132 respectively disposed in the heating channels 122, neighboring in the circumferential direction, contact each other in the circumferential direction. For instance, as illustrated in FIG. 7C and the like, a pointed portion 133 is disposed between the second tapered portions 132 neighboring in the circumferential direction. The pointed portion 133 is constituted of the second tapered portions 132 neighboring in the circumferential direction, and is pointed toward the axial direction other side Db. Note that, if the second tapered portions 132 neighboring in the circumferential direction make a point contact, the pointed portion 133 has a point shape viewed from the axial direction, and is a contact point thereof. In addition, if the second tapered portions 132 neighboring in the circumferential direction make a line contact, the pointed portion 133 is a line shape viewed from the axial direction, and is a ridge line thereof (see FIGS. 7C and 8B). In this way, viewed from the axial direction, each of the second tapered portions 132 can be larger. Thus, the gas flow of the sprayed body of the liquid material LQ can flow smoothly into the heating channel 122. In addition, the area of the surface formed on the axial direction one end surface of the spray chamber 121 can be reduced or eliminated. Therefore, occurrence of residue of the liquid material LQ can be further suppressed or prevented.

However, without limiting to the example describe above, in at least some of the heating channels 122, the second tapered portions 132 disposed at the axial direction other end of at least two of the heating channels 122 neighboring in the circumferential direction around the center axis CA (i.e., the second tapered portions 132 neighboring in the circumferential direction) may be apart from each other in the circumferential direction with an interval. For instance, as illustrated in FIG. 7B and the like, between the second tapered portions 132 neighboring in the circumferential direction, there is disposed a part of the axial direction one end surface of the spray chamber 121 (i.e., a part of the inner surface of the spray chamber 121 that faces the axial direction other side Db). In this way, viewed from the axial direction, each of the second tapered portions 132 can have a size such that the second tapered portions 132 do not contact each other. Therefore, the second tapered portions 132 can be formed easily.

In at least one of the heating channels 122, it is preferred that a first axis JF is different from a second axis JT, and it is more preferred that it is apart from the second axis JT outward in the radial direction with respect to the center axis CA. Note that the first axis JF is the center axis of the heating channel 122, and passes through the center of the heating channel 122 so as to extend in the axial direction. The second axis JT is the center axis of the frustum shape of the second tapered portion 132 disposed in the heating channel 122, and passes through the barycenter of the second tapered portion 132 having a frustum shape so as to extend in the axial direction. For instance, in FIGS. 7A to 8B, the first axis JF of each of the heating channels 122 is apart outward in the radial direction from the second axis JT of the second tapered portion 132 disposed at the axial direction other end of the heating channel 122.

By shifting the center axis of the heating channel 122 (i.e., the first axis JF) from the center axis of the second tapered portion 132 (i.e., the second axis JT), it is possible to improve flexibility in designing layout of the second tapered portions 132. In addition, the outer diameter of the second tapered portion 132 at the axial direction other end can be increased more. Further, by shifting the first axis JF from the second axis JT outward in the radial direction, the area of the second tapered portion 132 (in particular, an inward part in the radial direction) can be increased more. Therefore, the area of the surface formed on the axial direction one end surface of the spray chamber 121 can be reduced more or eliminated. Thus, occurrence of residue of the liquid material LQ can be further suppressed or prevented.

However, the example describe above does not exclude a structure in which the first axis JF is apart from the second axis JT in another direction perpendicular to the axial direction (e.g. inward in the radial direction, the circumferential direction), in at least one of the heating channels 122, and does not exclude a structure in which the first axis JF of the heating channel 122 coincided with the second axis JT in the heating channel 122, in at least one of the heating channels 122.

As long as there is no contradiction, the tapered portion 13 may include both the first tapered portion 131 and the second tapered portion 132, as illustrated in FIGS. 8A and 8B. Alternatively, the tapered portion 13 may include only the first tapered portion 131 as illustrated in FIGS. 3A, 3B, 6A, and 6B, or may include only the second tapered portion 132 as illustrated in FIGS. 7A and 7B. In other words, it is sufficient that the tapered portion 13 includes at least one of the first tapered portion 131 and the second tapered portion 132 that is disposed at the axial direction other end of at least one of the heating channels 122.

Note that in FIGS. 1 to 8B, on the axial direction other end surface of the spray chamber 121, there is disposed a tapered surface (without numeral) having a conical shape whose outer diameter decreases toward the axial direction other side Db. However, without limiting to this example, the axial direction other end surface of the spray chamber 121 may be a flat surface.

Other than that, as illustrated in FIGS. 6A, 6B, and 7C to 8B, the axial direction one end surface of the spray chamber 121 may be provided with a protruding portion 124 that protrudes to the axial direction other side Db. Outer diameter of the protruding portion 124 viewed from the axial direction decreases toward the axial direction other side Db. The protruding portion 124 may have a frustum shape as illustrated in FIG. 7C, or may have a conical shape with a pointed tip as illustrated in FIGS. 6A, 6B, 8A, and 8B. In addition, in FIGS. 6A and 6B, the axial direction other end of each of the heating channels 122 is disposed on the axial direction other end surface of the protruding portion 124. Thus, the gas-liquid mixture MG flowing along the axial direction other end surface of the protruding portion 124 can flow to each of the heating channels 122 more smoothly.

It is preferred that the axial direction other end of the protruding portion 124 is pointed toward the axial direction other side Db, and faces the spray hole 111 in the axial direction, which is disposed on the axial direction other end surface of the spray chamber 121 (see FIG. 8A and the like). The residue of the sprayed body of the liquid material LQ tends to adhere to a region of the axial direction one end surface of the spray chamber 121, the region facing the spray hole 111 in the axial direction, and its vicinity. Therefore, by disposing the protruding portion 124 that is pointed toward the axial direction other side Db (i.e., toward the spray hole 111), adhesion of the residue to the region and its vicinity described above can be suppressed or prevented.

However, the example describe above does not exclude a structure in which the axial direction other end of the protruding portion 124 is not pointed toward the axial direction other side Db, the structure in which the axial direction other end of the protruding portion 124 does not face the spray hole 111 in the axial direction, and the structure in which the protruding portion 124 is not disposed on the axial direction one end surface of the spray chamber 121.

In addition, in the first to sixth structure examples of the communication portion 123 described above, at least a part of the structures can be combined for implementation, as long as there is no contradiction.

Next, the vaporizer 3 includes a heat exchange element 15. The heat exchange element 15 is disposed inside each of the heating channels 122, and contacts the inner surface of the heating channel 122 at a predetermined position. The heat exchange element 15 is made of a metal material having thermal conductivity, for example. As the metal material described above, there are stainless steel (SUS), copper, aluminum, titanium, and the like, for example.

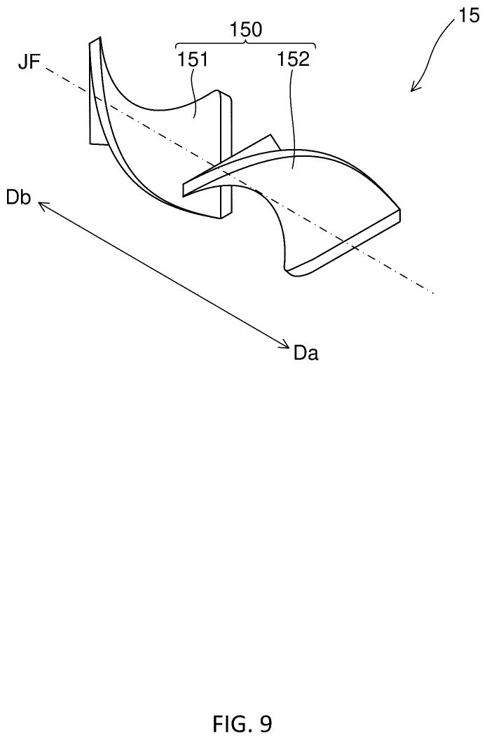

As the heat exchange element 15, a static mixer is adopted, for example. FIG. 9 is a perspective view of a part of the static mixer as the heat exchange element 15 provided to the vaporizer 3 described above. The static mixer has a structure in which a plurality of fins 150 are connected in the axial direction. Note that the number of the fins 150 is not particularly limited as long as being two or more. Each of the fins 150 can stir the liquid material LQ in the heating channel 122. In this way, more complex turbulence is generated in the heating channel 122, so that heat exchange efficiency and vaporizing performance of the liquid material LQ can be improved.

For instance, the plurality of fins 150 includes a first fin 151 and a second fin 152. The first fin 151 has a shape obtained by twisting a flat plate in a clockwise direction about its center axis (without numeral), viewed from the axial direction one side Da. The second fin 152 has a shape obtained by twisting a flat plate in a counterclockwise direction about its center axis, viewed from the axial direction one side Da. The first fins 151 and the second fins 152 are disposed alternately in the axial direction and connected to each other by welding or the like. With this structure, in the heating channel 122, the first fin 151 or the second fin 152 repeats division of passage for the liquid material LQ (division of passage into front and back sides of the fin 150) and joining of the divided passages. In this way, more complex turbulence is generated securely in the heating channel 122, so that vaporizing performance can be improved.

Note that the structure of the static mixer is not limited to the example of FIG. 9. For instance, at least one flat plate of the first fin 151 and the second fin 152 may have at least one through hole extending in the axial direction or the thickness direction, or may have a notch on the periphery. By disposing the through hole in the static mixer, the static mixer can generate a flow path passing the through hole. Thus, complex turbulence can be generated securely in the heating channel 122, and vaporizing performance can be improved more.

In addition, as the heat exchange element 15 to be disposed in at least one of the heating channels 122, it is possible to dispose filler instead of the static mixer. The filler includes metal particulate matter and filters disposed on the upstream side and the downstream side of the particulate matter in the flow path. The fillers can realize heat exchange efficiency equal to that of the static mixer. Therefore, by using the fillers instead of the static mixer, vaporizing performance of the liquid material LQ can be improved, and vaporization of the liquid material LQ at large flow rate can be realized.

In addition, the liquid material vaporizing device 1 of this embodiment uses an internal mixing method in which the liquid material LQ and the carrier gas CG are mixed in the liquid material supply portion 2. However, without limiting to this example, the liquid material vaporizing device 1 may use an external mixing method in which the liquid material LQ and the carrier gas CG are mixed in the outside of the liquid material supply portion 2. In the external mixing method, for example, the liquid material supply portion 2 introduces the liquid material LQ into the vaporizing portion 12 through the nozzle 11, and introduces the carrier gas CG into the vaporizing portion 12 via another route. Even in this external mixing method, by adopting the structure of the vaporizer 3 of this embodiment, vaporizing performance of the liquid material LQ can be improved, and vaporization of the liquid material LQ at large flow rate can be realized.

Although the embodiment of the present invention is described above, but the scope of the present invention is not limited to the embodiment, but can be expanded or modified within the scope of the invention without deviating from the spirit thereof.

Hereinafter, the embodiment described above is described in an overall manner.

For instance, the vaporizer 3 disclosed in this specification (first structure) is the vaporizer 3 configured to heat and vaporize the liquid material LQ, comprising:
the spray chamber 121 into which the liquid material LQ is sprayed;
the plurality of heating channels 122 extending from the spray chamber 121 to at least the axial direction one side Da; and
the tapered portion 13 configured to be tapered off toward the axial direction in the communication portion 123 between the spray chamber 121 and the heating channel 122.

The vaporizer 3 of the first structure described above may have a structure (second structure) in which
the tapered portion 13 includes the first tapered portion 131 disposed on the axial direction one end surface of the spray chamber 121, and
the first tapered portion 131 has a curved surface of a conical shape whose outer diameter decreases toward the axial direction one side Da or other side Db.

In addition, the vaporizer 3 of the first or second structure described above may have a structure (third structure) in which
the tapered portion 13 includes the second tapered portion 132 disposed on an inner peripheral surface at the axial direction other end of at least one of the heating channels 122, and
the second tapered portion 132 is a curved surface of a frustum shape whose outer diameter decreases toward the axial direction one side Da.

In addition, the vaporizer 3 of the third structure described above may have a structure (fourth structure) in which
in at least two of the heating channels 122 neighboring in the circumferential direction, the pointed portion 133 is disposed between the second tapered portions 132 disposed respectively in the heating channels 122, and
the pointed portion 133 is constituted of the second tapered portions 132 neighboring in the circumferential direction, and is pointed toward the axial direction other side Db.

In addition, the vaporizer 3 of the third or fourth structure described above may have a structure (fifth structure) in which in at least two of the heating channels 122 neighboring in the circumferential direction, a part of the axial direction one end surface of the spray chamber 121 is disposed between the second tapered portions 132 disposed respectively in the heating channels 122.

In addition, the vaporizer 3 of any one of the third to fifth structures described above may have a structure (sixth structure) in which in at least one of the heating channels 122, the first axis JF passing through the center of the heating channel, so as to extend in the axial direction, is different from the second axis JT passing through the barycenter of the frustum shape of the second tapered portion 132 disposed in the heating channel 122, so as to extend in the axial direction.

In addition, the vaporizer 3 of any one of the first to sixth structures described above may have a structure (seventh structure) in which
the protruding portion 124 configured to protrude to the axial direction other side Db is disposed on the axial direction one end surface of the spray chamber 121, and
the axial direction other end of the protruding portion 124 is pointed toward the axial direction other side Db, and faces the spray hole 111 disposed in the axial direction other end surface of the spray chamber 121 in the axial direction.

In addition, the vaporizer 3 of any one of the first to seventh structures described above may have a structure (eighth structure) in which the residue preventing layer 14 that repels the liquid material LQ is disposed on an inner surface of at least one of the spray chamber 121 and the tapered portion 13.

In addition, the vaporizer 3 of any one of the first to eighth structures described above may have a structure (ninth structure) in which at least some of the heating channels 122 are arranged in the circumferential direction around the center axis CA passing through the spray hole 111 disposed in the axial direction other end surface of the spray chamber 121 so as to extend in the axial direction.

In addition, the vaporizer 3 of any one of the first to eighth structures described above may have a structure (tenth structure) further comprising the cylinder portion 32 extending to the axial direction one side Da at the axial direction one end of the vaporizer 3, in which
the axial direction other end of the cylinder portion 32 surrounds the axial direction one end of the heating channels 122, and
the inner diameter Wa1 (or Wa2) of the axial direction one end of the cylinder portion 32 is different from the inner diameter Wb1 (or Wb2) of the axial direction other end of the cylinder portion 32.

In addition, a liquid material vaporizing device 1 disclosed in this specification (eleventh structure) includes:
the vaporizer 3 of any one of the first to tenth structures; and
the liquid material supply portion 2 configured to supply the liquid material LQ to the vaporizer 3.

The present invention can be used for a vaporizer that is disposed in a pre-stage of a semiconductor manufacturing apparatus, for example.

What is claimed is:

1. A vaporizer configured to heat and vaporize liquid material, comprising:
a spray chamber into which the liquid material is sprayed;
a plurality of heating channels extending from the spray chamber to at least an axial direction one side; and
a tapered portion configured to be tapered off toward the axial direction in a communication portion between the spray chamber and the heating channel.

2. The vaporizer according to claim 1, wherein
the tapered portion includes a first tapered portion disposed on the axial direction one end surface of the spray chamber, and
the first tapered portion is a curved surface having a conical shape whose outer diameter decreases toward the axial direction one side or other side.

3. The vaporizer according to claim 1, wherein
the tapered portion includes a second tapered portion disposed on an inner peripheral surface at an axial direction other end of at least one of the heating channels, and
the second tapered portion is a curved surface of a frustum shape whose outer diameter decreases toward the axial direction one side.

4. The vaporizer according to claim 2, wherein
the tapered portion includes a second tapered portion disposed on an inner peripheral surface at an axial direction other end of at least one of the heating channels, and
the second tapered portion is a curved surface of a frustum shape whose outer diameter decreases toward the axial direction one side.

5. The vaporizer according to claim 3, wherein
in at least two of the heating channels neighboring in the circumferential direction, a pointed portion is disposed between the second tapered portions disposed respectively in the heating channels, and
the pointed portion is constituted of the second tapered portions neighboring in the circumferential direction, and is pointed toward an axial direction other side.

6. The vaporizer according to claim 4, wherein
in at least two of the heating channels neighboring in the circumferential direction, a pointed portion is disposed between the second tapered portions disposed respectively in the heating channels, and
the pointed portion is constituted of the second tapered portions neighboring in the circumferential direction, and is pointed toward an axial direction other side.

7. The vaporizer according to claim 3, wherein in at least two of the heating channels neighboring in the circumferential direction, a part of the axial direction one end surface of the spray chamber is disposed between the second tapered portions disposed respectively in the heating channels.

8. The vaporizer according to claim 4, wherein in at least two of the heating channels neighboring in the circumferential direction, a part of the axial direction one end surface of the spray chamber is disposed between the second tapered portions disposed respectively in the heating channels.

9. The vaporizer according to claim 5, wherein in at least two of the heating channels neighboring in the circumferential direction, a part of the axial direction one end surface of the spray chamber is disposed between the second tapered portions disposed respectively in the heating channels.

10. The vaporizer according to claim 6, wherein in at least two of the heating channels neighboring in the circumferential direction, a part of the axial direction one end surface of the spray chamber is disposed between the second tapered portions disposed respectively in the heating channels.

11. The vaporizer according to claim 3, wherein in at least one of the heating channels, a first axis passing through the center of the heating channel, so as to extend in the axial direction, is different from a second axis passing through the barycenter of the frustum shape of the second tapered portion disposed in the heating channel, so as to extend in the axial direction.

12. The vaporizer according to claim 4, wherein in at least one of the heating channels, a first axis passing through the center of the heating channel, so as to extend in the axial direction, is different from a second axis passing through the barycenter of the frustum shape of the second tapered portion disposed in the heating channel, so as to extend in the axial direction.

13. The vaporizer according to claim 5, wherein in at least one of the heating channels, a first axis passing through the center of the heating channel, so as to extend in the axial direction, is different from a second axis passing through the barycenter of the frustum shape of the second tapered portion disposed in the heating channel, so as to extend in the axial direction.

14. The vaporizer according to claim 6, wherein in at least one of the heating channels, a first axis passing through the center of the heating channel, so as to extend in the axial direction, is different from a second axis passing through the barycenter of the frustum shape of the second tapered portion disposed in the heating channel, so as to extend in the axial direction.

15. The vaporizer according to claim 1, wherein
a protruding portion configured to protrude to an axial direction other side is disposed on the axial direction one end surface of the spray chamber, and
the axial direction other end of the protruding portion is pointed toward the axial direction other side and faces a spray hole disposed in the axial direction other end surface of the spray chamber in the axial direction.

16. The vaporizer according to claim 1, wherein a residue preventing layer configured to repel the liquid material is disposed on an inner surface of at least one of the spray chamber and the tapered portion.

17. The vaporizer according to claim 1, wherein at least some of the heating channels are arranged in a circumferential direction around a center axis passing through a spray hole disposed in the axial direction other end surface of the spray chamber so as to extend in the axial direction.

18. The vaporizer according to claim 1, further comprising a cylinder portion extending to the axial direction one side at the axial direction one end of the vaporizer, wherein
the axial direction other end of the cylinder portion surrounds the axial direction one end of the heating channels, and
inner diameter of the axial direction one end of the cylinder portion is different from inner diameter of the axial direction other end of the cylinder portion.

19. A liquid material vaporizing device comprising:
the vaporizer according to claim 1; and
a liquid material supply portion configured to supply the liquid material to the vaporizer.
